(19) United States
(12) Patent Application Publication
(10) Pub. No.: US 2012/0049359 A1
(43) Pub. Date: Mar. 1, 2012

(54) BALL GRID ARRAY PACKAGE

(76) Inventor: Wen-Jeng FAN, Hukou Shiang (TW)

(21) Appl. No.: 12/871,452

(22) Filed: Aug. 30, 2010

(51) Int. Cl. H01L 23/498

(52) U.S. Cl. 257/738; 257/E23.069

(57) ABSTRACT

A BGA package comprises a substrate, a chip disposed on the substrate, and a plurality of solder balls disposed under the substrate. The substrate further has a plurality of ball pads and a solder mask having a plurality of openings to expose the ball pads where the ball pads include two or more non-signal pads. Solder mask further has a trench connecting the ones of the openings on the non-signal pads where the trench is filled with solder paste so that the solder balls bonded to the non-signal pads are electrically connected together to achieve power integrity and to reduce numbers of power/ground layers to make the package thinner and the substrate cost lower.

### FIELD OF THE INVENTION

The present invention relates to packaged semiconductor devices, especially to BGA (Ball Grid array) packages.

### BACKGROUND OF THE INVENTION

Ball grid array packages (BGA packages) are widely implemented in IC products with internally disposed semiconductor IC and with multiple-rows of solder balls arranged in an array to joint to an external printed circuit board having the advantages of smaller dimensions with high circuitry density when comparing to conventional packages with external leads extended from the encapsulant.

There are four primary components of a BGA package: substrate, chip, encapsulant, and solder balls. One surface of the substrate is the joint surface for SMT and the other surface is the die-attaching surface for chip. Usually substrate is a printed circuit board with fine-pitch circuitry where multiple metal layers in substrate include different signal wiring layers, power plane, and ground plane which are designed and manufactured for more I/O terminals and for dimension miniature.

As shown in FIG. 1 and FIG. 2, a conventional BGA package primarily comprises a substrate 110, a plurality of solder balls 130, and an encapsulant 160 to encapsulate chip(s). The substrate 110 has a first surface 111 and a second surface 112 where the first surface 111 is the die-attaching surface configured for being encapsulated by the encapsulant 160 and the second surface is the external surface corresponding to the first surface 111. The substrate 110 serves as a chip carrier as well as an electrical transmission media where signal wiring layers, ground plane 118 and power plane 119 are internally formed inside the substrate 110. The circuitry on the second surface 112 is covered by a solder mask 114 where a plurality of openings 114A are formed in the solder mask 114 to expose the ball pads 113 of the circuitry. The solder balls 130 are reflowed to bond onto the corresponding ball pads 113 so that BGA packages can be SMT mounted onto an external printed circuit board by the solder balls 130. A plurality of via 117 or PTH are further disposed inside the substrate 110 where there are several ground pads connected to Vss and several power pads connected to Vcc among the ball pads 113 through the corresponding via 117 to electrically connect to the corresponding ground plane 118 and power plane 119 respectively to achieve power integrity to reduce package inductance caused by return current and by power switching noise to further reduce EMI effects. However, as shown in FIG. 3, substrates with multiple layers have higher substrate cost and thicker substrate thickness.

Hung had proposed a flip-chip package structure for improvement such as disclosed in U.S. Pat. No. 6,825,568 where bump pads with the rectangular or strip shapes having dimensions larger than the ball pads are disposed on the substrate as well as the chip as the non-signal pads for chips. Moreover, larger solder area bumps with volumes much greater than regular solder balls are bonded onto the larger bump pads of the substrate and the chip, i.e., to form larger dimension non-spherical area bumps. Even though the electrical performance and heat dissipation can be enhanced, however, the heights and the surface tension of larger solder area bumps are not good for SMT bonding leading to false soldering of solder balls. Furthermore, larger bump pads certainly impact the layout of high-density circuitry between the substrate and the chip as well as heat dissipation.

### SUMMARY OF THE INVENTION

The main purpose of the present invention is to provide a BGA package structure to effectively reduce the power/ground metal layers disposed inside the substrate without affecting the electrical performance and heat dissipation to make thinner semiconductor packages and to further reduce substrate cost.

According to the present invention, a BGA package is revealed comprising a substrate, a chip, and a plurality of solder balls where the substrate has a first surface and a second surface. The substrate further has a plurality of ball pads and a solder mask formed on the second surface where the solder mask has a plurality of openings to expose the ball pads. The ball pads include two or more non-signal pads. The chip is disposed on the substrate. The solder balls are bonded onto the corresponding ball pads of the substrate. Additionally, the solder mask further has a trench connecting ones of the openings exposing the non-signal pads. The trench is filled with solder paste to electrically connect ones of the solder balls disposed on the non-signal pads to achieve power integrity.

The BGA package according to the present invention has the following advantages and effects:
1. Through filling the specific trench with solder paste to electrically connect to the ones of the solder balls disposed on the non-signal pads as a technical mean, power integrity is achieved between the non-signal pads to reduce numbers of metal layers designed for power plane and ground plane without affecting electrical performance and heat dissipation to make thinner semiconductor packages and to further reduce substrate cost.
2. Through filling the specific trench with solder paste to electrically connect to the ones of the solder balls disposed on the non-signal pads as a technical mean, larger solder bumps are eliminated from the package structure so that solder paste can be applied to hold the solder balls on the ball pads in a single reflow process to reduce manufacture costs and to meet the substrate layout requirement of high-density circuitry with lower cost.

### DESCRIPTION OF THE DRAWINGS

FIG. 1 is a partially enlarged cross-sectional view of a conventional BGA package.

FIG. 2 is a partial bottom view of a conventional BGA package.

FIG. 3 is a partially enlarged cross-sectional view of the substrate of a conventional BGA package.

FIG. 4 is a cross-sectional view of a BGA package according to the first embodiment of the present invention.

FIG. 5 is a partially enlarged cross-sectional view of a BGA package according to the first embodiment of the present invention.

FIG. 6 is a partial bottom view of a BGA package according to the first embodiment of the present invention.

FIG. 7 is a partially three-dimensional bottom view of a BGA package according to the first embodiment of the present invention.

FIG. 8 is a partially enlarged cross-sectional view of the substrate of the BGA package according to the first embodiment of the present invention.

FIG. 9 is a cross-sectional view of a BGA package according to the second embodiment of the present invention.

FIG. 10 is a partially enlarged cross-sectional view of a BGA package according to the second embodiment of the present invention.

FIG. 11 is a cross-sectional view of a BGA package according to the third embodiment of the present invention.

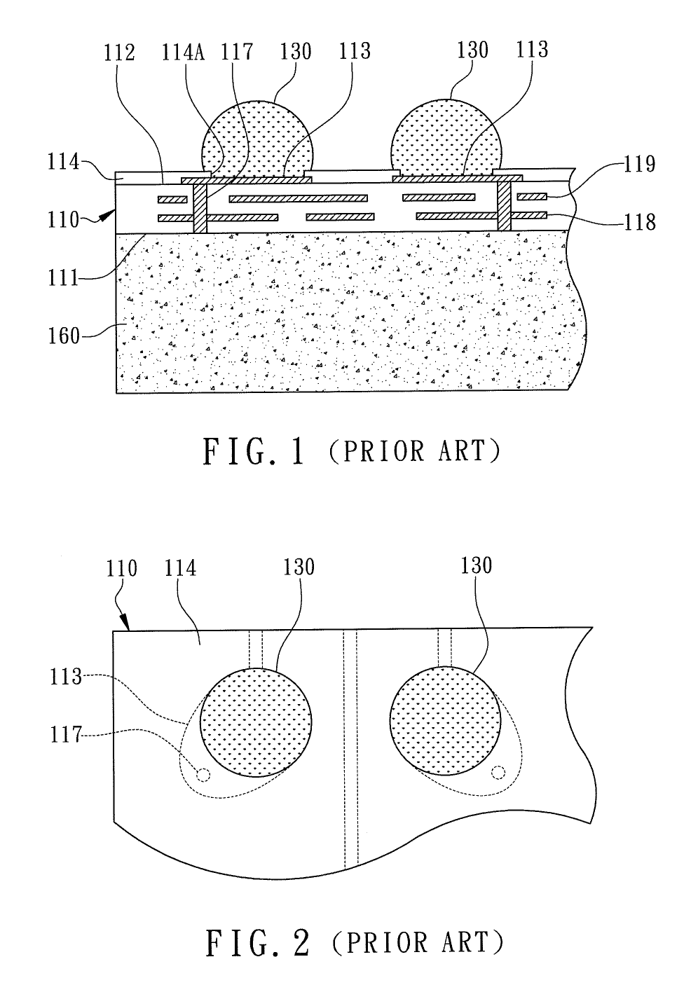

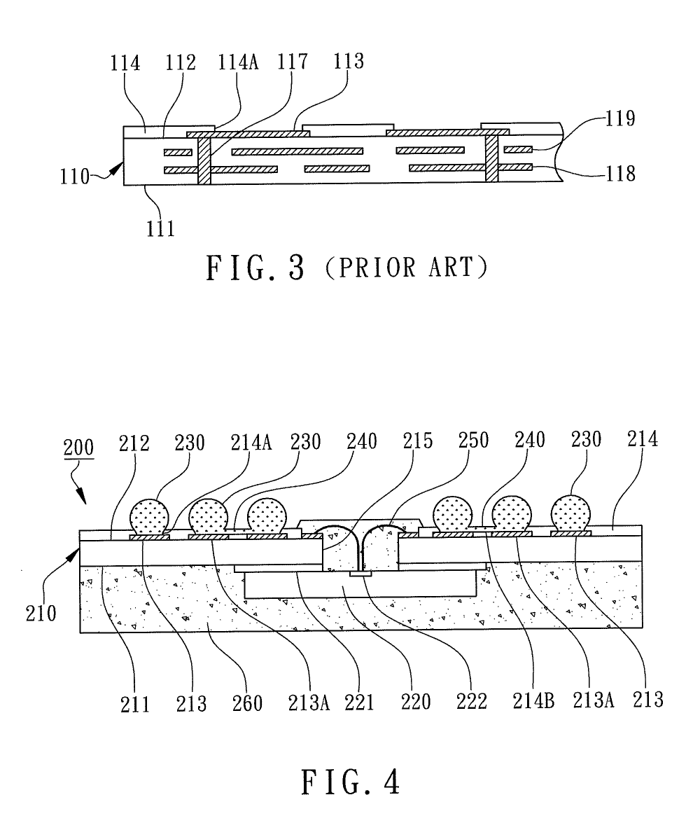

### DETAILED DESCRIPTION OF THE INVENTION

With reference to the attached drawings, the present invention is described by means of the embodiment(s) below where the attached drawings are simplified for illustration purposes only to illustrate the structures or methods of the present invention by describing the relationships between the components and assembly in the present invention. Therefore, the components shown in the figures are not expressed with the actual numbers, actual shapes, actual dimensions, nor with the actual ratio. Some of the dimensions or dimension ratios have been enlarged or simplified to provide a better illustration. The actual numbers, actual shapes, or actual dimension ratios can be selectively designed and disposed and the detail component layouts may be more complicated.

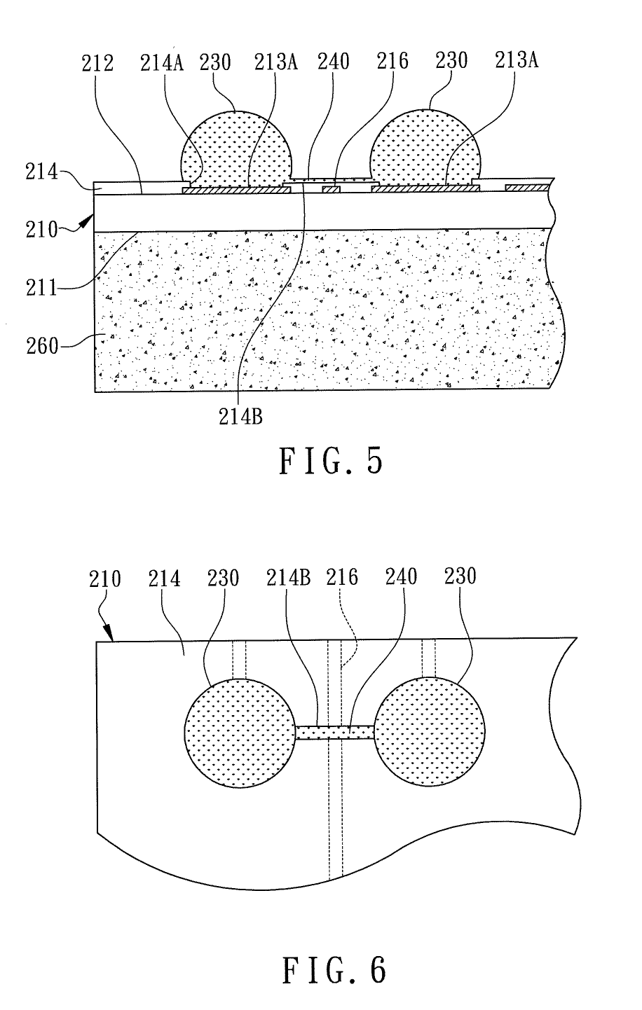

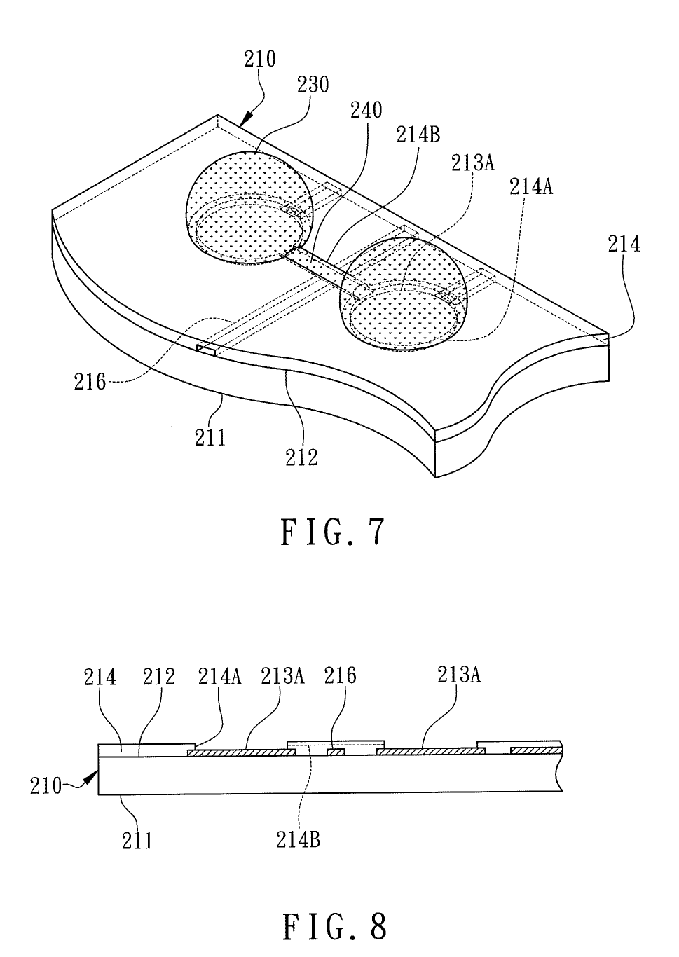

According to the first embodiment of the present invention, a BGA package is illustrated in FIG. 4 and FIG. 5 for cross-sectional views, FIG. 6 for a partial bottom view, and FIG. 7 for a partial three-dimensional bottom view. The BGA package 200 primarily comprises a substrate 210, a chip 220, and a plurality of solder balls 230. As shown in FIG. 4 in the present embodiment, a window-BGA package is illustrated but not limited. The present invention can be implemented in other known BGA packages or flip-chip packages.

As shown in FIG. 4, the substrate 210 is a chip carrier to provide electrical interconnections for the BGA packages 200 where the substrate 210 is normally a printed circuit board, but also can be ceramic substrate or thin flexible wiring film with circuitry. The substrate 210 has a first surface 211 and a second surface 212. In this embodiment, the first surface 211 is the die-attaching surface as well as the encapsulated surface encapsulated by an encapsulant and the second surface 212 is an external surface opposing to the first surface 211 as the disposed surface for the solder balls 230. The substrate 210 further has a plurality of ball pads 213 and a solder mask 214 formed on the second surface 212. The ball pads 213 include two or more non-signal pads 213A to electrically connect the power or ground terminals in the chip 220 to an external PWB through the corresponding solder balls to provide power or to be reference voltages for ground. The ball pads 213 are formed on the second surface 212 or on the first surface 211. As shown in FIG. 4 and FIG. 5 in the present embodiment, the ball pads 213 are disposed on and exposed from the second surface 212 of the substrate 210. A plurality of openings 214A are disposed on the solder mask 214 to expose the ball pads 213 including the non-signal pads 213A. The ball pads 213 are arranged in multiple rows on the second surface 212 with circular shapes where the shapes and dimensions of the non-signal pads 213A can be the same as the ball pads 213 of signal pads. The non-signal pads 213A can be arranged at the corners, at the sides, or at the center of the substrate 210. In the present embodiment, as shown in FIG. 4, the non-signal pads 213A are closely arranged to each other adjacent to the center of the substrate 210.

The solder mask 214 can be an electrical-isolation surface coating to protect the circuitry from solder paste contaminations and is also known as solder resist or can be other surface protection layers with the function of solder resist. The solder mask 214 can provide surface isolation for the substrate 210 to prevent the exposure of the circuitry and the substrate core from contaminations. To be more specific, as shown in FIG. 5, the diameters of the openings 214A of the solder mask 214 are smaller than the diameters of the ball pads 213 including non-signal pads 213A, i.e., the peripheries of the non-signal pads 213A are covered by the solder mask 214 to provide better adhesion to the substrate 210 so that the non-signal pads 213A are solder mask defined (SMD). In the present embodiment, at least a signal trace 216 covered by the solder mask 214 is further disposed on the second surface 212 of the substrate 210. The signal trace 216 crosses between the non-signal pads 213A under the trench 214B and is electrically connected to one of signal pads among the ball pads 213 but not connected to the non-signal pads 213A to meet the substrate layout requirements of high-density circuitry.

As shown in FIG. 4 in the present embodiment, the chip 220 is disposed on the first surface 211 of the substrate 210 where the chip is a semiconductor device with IC such as memory, logic, or ASIC. The chip 220 is singulated from a wafer. In the present embodiment, the active surface 221 of the chip 220 is attached to the first surface 211 of the substrate 210 where the substrate 210 further has a penetrating slot 215 to expose the bonding pads 222 disposed on the active surface 221 of the chip 220. The penetrating slot 215 is located at the center of the substrate 210 and the bonding pads 222 are arranged at the center of the active surface 221 of the chip 220, i.e., the central bonding pads layout. The active surface 221 of the chip 220 is attached to the first surface 211 of the substrate 210 by tapes, B-stage adhesive, or die-attach material (DAM). A plurality of bonding fingers are disposed at two corresponding sides of the penetrating slot 215 of the substrate 210 which are electrically connected to the ball pads 213 including non-signal pads 213A by routing traces. Moreover, the BGA package 200 further comprises a plurality of electrically connecting components 250 passing through the penetrating slot 215 to electrically connect the bonding pads 222 to the bonding fingers of the substrate 210. In the present embodiment, the electrically connecting components 250 are gold wires or copper wires formed by wire bonding to electrically connect the chip 220 to the substrate 210. In another variation of embodiment, the electrically connecting components 250 may be inner leads extended from the substrate 210. The BGA package further comprises an encapsulant 260 formed the first surface 211 of the substrate 210 to encapsulate the chip 220 where the encapsulant 260 may be an epoxy molding compound (EMC) formed by transfer molding formed on the first surface 211 of the substrate 210. In the present embodiment, the encapsulant 260 can further be formed in the penetrating slot 215 and parts of the second surface 212 around the penetrating slot 215 to encapsulate the electrically connecting components 250 to provide appropriate packaging protection to avoid electrical short and external contaminations.

As shown in FIG. 4, the solder balls 230 are bonded onto the ball pads 213 of the substrate 210 including the non-signal pads 213A. Each of the ball pad 213 including the non-signal pads 213A has a jointed solder ball 230 bonded for external electrical connections. More specifically, as shown in FIG. 5, the solder mask 214 has a trench 214B connecting ones of the openings 214A exposing the non-signal pads 213A where the trench 214B is filled with solder paste 240 to electrically connect ones of the solder balls 230 disposed on the non-signal pads 213A to achieve power integrity. Therein, the non-signal pads 213A are either ground pads or power pads and are connected to the corresponding solder balls 230 by the solder paste 240. Accordingly, the connection of the non-signal pads 213A by the solder paste 240 is either ground-to-ground connection or power-to-power connection, not ground-to-power connection. It is better that the non-signal pads 213A have the same dimensions with the same outlines as the rest of the ball pads 213 for the bonding of the solder balls 230. In order not to change the shape of the solder balls 230, the width of the trench 214B is not greater than half of the diameter of the openings 214A. To be described in more detail, as shown in FIG. 5 and FIG. 7, the trench 214B can be formed by laser cutting without penetrating through the solder mask 214. Preferably, the depth of the trench 214B can not exceed the solder-bonded surfaces of the non-signal pads 213A without penetrating through the signal traces 216 disposed on the second surface 212. To be in detail, as shown in FIG. 5, there is a gap formed between the bottom of the trench 214B and the signal traces 216 without direct contacts. The depth of the trench 214B ranges from 30% to 80% of the solder mask thickness which ranges between 10 um to 40 um. If the solder mask thickness is not thick enough, multiple coating of the solder mask 214 on the second surface 212 of the substrate 210 can be implemented. Moreover, in a preferred embodiment, as shown in FIG. 4 and FIG. 6, a distance from center to center of the non-signal pads 213A is equal to the average pitch of the ball pads 213 and the trench 214B is linear without curves so that the parasitic electrical parameters can be reduced by forming the trench 214B between the non-signal pads 213A in the shortest distance.

To be more specific, the solder balls 230 are formed by solder placement, screen printing, or stencil printing where solder balls are placed on or solder paste are printed on the ball pads 213 including the non-signal pads 213A. Individual solder balls can be attached to the corresponding ball pads 213 including the non-signal pads 213A and the solder paste 240 can be filled into the trench 214B of the solder mask 214 by automatic ball placement technology with preformed solder paste processes. Then, the solder balls 230 permanently joint to the ball pads 213 including the non-signal pads 213A through a high-temperature reflow oven. Or flux is directly applied on the ball pads 213 including the non-signal pads 213A and solder paste 240 is filled into the trench 214B by dispensing. Therefore, through filling the trench 214B with solder paste 240 to electrically connect to the solder balls disposed on the non-signal pads 213A as a technical mean, power integrity is achieved between non-signal pads 213A by skipping the substrate to reduce numbers of metal layers designed for power planes and ground planes inside the substrate 210 without affecting electrical performance and heat dissipation to make the BGA packages thinner and substrate cost lower.

In another preferred embodiment, the solder paste 240 and the solder balls 230 are made of the same material such as lead tin so that solder paste can be applied to hold the solder balls on the ball pads in a single reflow process to reduce manufacture costs and to meet the substrate layout requirement of high-density circuitry. Using the existing method to form solder balls, flux is applied on the ball pads 213 including the non-signal pads 213A and inside the trench 214B. Then, solder paste 240 is applied and solder balls are placed. During reflow processes, the package is placed into a heating system to make the solder paste 240 and solder balls 230 melted and flowing. The flux applied inside the trench 214B is able to enhance the melted solder paste to flow into the trench 214B. After reflow processes, the solder paste 240 inside the trench 214B is able to electrically connect to the solder balls 230 disposed on the non-signal pads 213A so that larger solder area bumps are eliminated from the package structure and the internal power/ground planes along the internal circuitry inside the substrate 210 are not essential.

As shown in FIG. 8 in the present embodiment, the substrate has one-single layer circuitry where there is no power/ground plane inside the substrate 210 to eliminate the complicated layout design and processes to achieve high-speed signal transmission and to reduce substrate manufacture costs where it was not limited that the substrate 210 can be a double-sided printed circuit board.

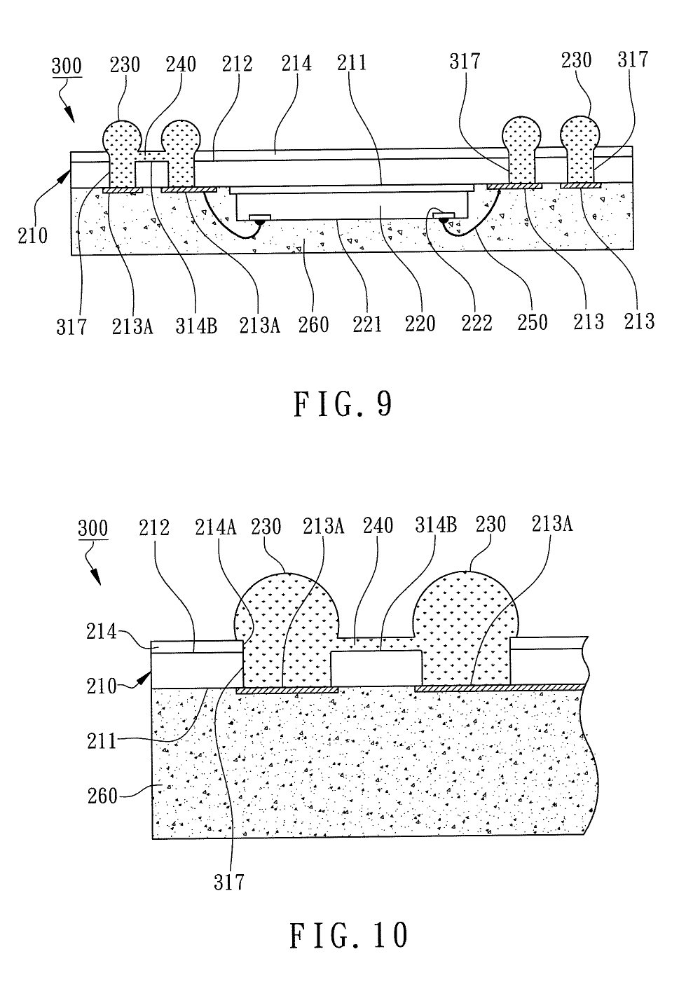

According to the second embodiment of the present invention, another BGA package is illustrated in FIG. 9 and FIG. 10 for cross-sectional views. The BGA package 300 primarily comprises a substrate 210, a chip 220, and a plurality of solder balls 230. If the major components are the same as described in the first embodiment, the same names and the same described numbers with the same functions will be used which will not be explained again.

As shown in FIG. 9 and FIG. 10 in the present embodiment, the ball pads 213 including the non-signal pads 213A are disposed on the first surface 211 of the substrate 210 and the corresponding routing signal traces are also disposed on the first surface. The solder mask 214 has a plurality of openings 214A aligned to the ball pads 213 and the trench 314B penetrate through the solder mask 214 where “penetrating” means that the formation of the trench 314B exposes the second surface 212 of the substrate 210 (the core layer of the substrate), i.e., the bottom of the trench 314B directly contacts with the second surface 212 of the substrate 210 so that it is not necessary to consider the impact of the trench depth to the routing traces where the trench 314B can be formed by mechanical routing, stencil printing, or lithography. To be more specific, the substrate 210 has a plurality of ball holes 317 penetrating through the first surface 211 to the second surface 212 of the substrate 210 to expose the ball pads 213 including the non-signal pads 213A where the solder balls 230 are bonded onto the ball pads 213 through the ball holes 317 so that there are some of the solder balls 230 dispose on the non-signal pads 213A to electrically connect to an external printed circuit board. The active surface 221 of the chip 220 is away from the substrate 210 and is electrically connected to the first surface 211 of the substrate 210 by a plurality of electrically connecting components 250. Therefore, there is no need to design signal circuitry on the second surface 212 of the substrate 210. To be in more detail, the ball holes 317 are formed by laser drilling or mechanical drilling.

As shown in FIG. 10 in the present embodiment, since the trench 314B penetrates through the solder mask 214 so that the trench 314B has a deeper depth without contact to the signal circuitry. During the reflow processes, the solder paste 240 easily reflow into the trench 314B to electrically connect to the ones of the solder balls 230 disposed on the non-signal pads 213A to achieve power integrity and to reduce the numbers of power/ground layers without affecting the electrical performance and heat dissipation.

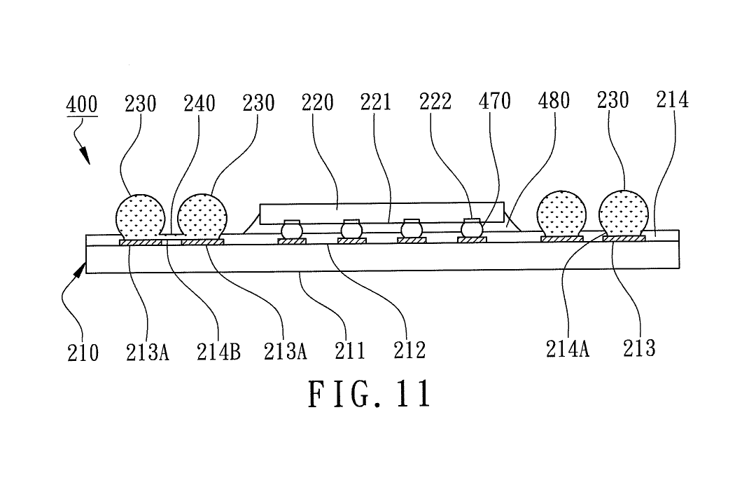

According to the third embodiment of the present invention, another BGA package is illustrated in FIG. 11 for a cross-sectional view. The BGA package 400 primarily comprises a substrate 210, a chip 220, and a plurality of solder balls 230 to be implemented in package on package (POP) such as the BGA package 400 can be used as the bottom package for POP where if the major components are the same as described in the first embodiment, the same names and the same described numbers with the same functions will be used which will not be explained again.

In the present embodiment, the chip 220 is disposed on the second surface 212 of the substrate 210 where the electrical connections between the chip 220 and the substrate 210 are flip chip to eliminate the conventional wire bonding processes. Bonding pads 222 are disposed on the active surface 221 of the chip 220 where a bump 470 is disposed on each bonding pad 222. The chip 220 is electrically connected to the substrate by the bumps 470. The bumps 470 may be solder bumps with a dimension smaller than the solder balls 230. In other embodiment, the solder bumps 470 may be pillar conductive bumps. Furthermore, an underfill material 480 fills the gap between the chip 220 and the substrate 210 to encapsulate the bumps 470 and to protect the active surface 221 of the chip 220.

The present invention is not limited and can implement to different semiconductor packages. One of the major features of the present invention is to form a trench 214B on the solder mask 214 on the second surface 212 of the substrate 210 where the trench 214B connects the ones of the openings 214A on the non-signal pads 213A. Solder paste 240 is filled into the trench 214B to electrically connect to the ones of the solder balls disposed on the non-signal pads 213A to achieve power integrity and to eliminate numbers of metal layers inside the substrate so that the BGA package 400 will become thinner without sacrificing electrical performance.

The above description of embodiments of this invention is intended to be illustrative but not limited. Other embodiments of this invention will be obvious to those skilled in the art in view of the above disclosure which still will be covered by and within the scope of the present invention even with any modifications, equivalent variations, and adaptations.

What is claimed is:

1. A BGA package comprising:
a substrate having a first surface, a second surface, a plurality of ball pads and a solder mask, wherein the ball pads include two or more non-signal pads, the solder mask is formed on the second surface and has a plurality of openings exposing the ball pads including the non-signal pads;
a chip disposed on the substrate; and
a plurality of solder balls bonded onto the ball pads of the substrate;
wherein the solder mask has a trench connecting ones of the openings exposing the non-signal pads, wherein solder paste fills inside the trench to electrically connect ones of the solder balls disposed on the non-signal pads to achieve the power integrity between the non-signal pads.

2. The BGA package as claimed in claim 1, wherein the solder paste and the solder balls are made of the same material.

3. The BGA as claimed in claim 1, wherein the ball pads are disposed on the second surface, and the trench is formed by laser cutting without penetrating through the solder mask.

4. The BGA package as claimed in claim 1, wherein the ball pads are disposed on the first surface where the trench penetrates through the solder mask.

5. The BGA package as claimed in claim 4, wherein the substrate has a plurality of ball holes penetrating through the first surface to the second surface to expose the ball pads including the non-signal pads.

6. The BGA package as claimed in claim 1, wherein a distance from center to center of the non-signal pads is equal to the average pitch of the ball pads, and the trench is linear.

7. The BGA package as claimed in claim 1, wherein an active surface of the chip is attached to the first surface of the substrate, wherein the substrate further has a penetrating slot to expose a plurality of bonding pads disposed on the active surface.

8. The BGA package as claimed in claim 7, further comprising a plurality of electrically connecting components electrically connecting the bonding pads to the substrate by passing through the penetrating slot.

9. The BGA package as claimed in claim 1, further comprising an encapsulant encapsulating the chip formed on the first surface of the substrate.

10. The BGA package as claimed in claim 1, wherein a plurality of peripheries of the non-signal pads are covered by the solder mask.

11. The BGA package as claimed in claim 1, wherein the depth of the trench is not exceeding the bonded surface of the non-signal pads.

12. The BGA package as claimed in claim 11, wherein the substrate has a signal trace disposed on the second surface of the substrate and covered by the solder mask, wherein the signal trace crosses between the non-signal pads under the trench without electrically connecting to the non-signal pads.

13. The BGA package as claimed in claim 1, wherein the width of the trench is not greater than half of the diameter of the openings.

14. The BGA package as claimed in claim 1, wherein the non-signal pads are either ground pads or power pads and are connected to the corresponding solder balls by the solder paste.

15. The BGA package as claimed in claim 1, wherein the non-signal pads have the same dimensions with the same outlines as the rest of the ball pads.
